(19) United States
(12) Patent Application Publication
(10) Pub. No.: US 2021/0373422 A1
(43) Pub. Date: Dec. 2, 2021

(54) LIQUID-CRYSTAL DISPLAY PROJECTOR

(71) Applicant: QISDA CORPORATION, Taoyuan City (TW)

(72) Inventor: Hung-Yen Huang, Taoyuan City (TW)

(21) Appl. No.: 17/324,112

(22) Filed: May 19, 2021

(30) Foreign Application Priority Data
May 26, 2020 (CN) 202010453417.9

(51) Int. Cl. G03B 21/16; G03B 21/00; H05K 7/20

(52) U.S. Cl. CPC G03B 21/16; G03B 21/006; G03B 21/20; H05K 7/2039; H05K 7/20145

(57) ABSTRACT

A liquid-crystal display projector includes a projection lens, an optical light-converging component, a plurality of liquid-crystal display panels, a plurality of connection cables, and a cover. The optical light-converging component is disposed adjacent to the projection lens. The liquid-crystal display panels are disposed adjacent to the optical light-converging component. The connection cables are connected to the liquid-crystal display panels respectively. The cover is disposed above the optical light-converging component and the liquid-crystal display panels to cover the optical light-converging component and the liquid-crystal display panels. The cover has at least one through hole for the connection cables to pass through.

### BACKGROUND OF THE INVENTION

### 1. Field of the Invention

The present invention relates to a liquid-crystal display projector, and more particularly to a dustproof structure for liquid-crystal display panels of a liquid-crystal display projector.

### 2. Description of the Prior Art

In general liquid-crystal display projectors, the liquid-crystal display panels are usually exposed. This structure configuration helps connection cables of the liquid-crystal display panel to connect with a system motherboard thereof. For example, a larger operating space is provided to the connection cables, so that when assembling the system motherboard, assembly personnel can pass the connection cables from one side of the system motherboard through the system motherboard to be connected to connectors on the other side of the system motherboard. However, dust is likely to accumulate on the liquid-crystal display panels. Although the housing of the projector itself has a certain degree of dustproof effect, the system heat dissipation fan will bring a little dust from the outside of the projector. The dust is likely to fall on the liquid-crystal display panels to affect the heat dissipation and operation of the liquid-crystal display panels.

### SUMMARY OF THE INVENTION

An objective of the invention is to provide a liquid-crystal display projector, which uses a cover to provide dustproof effect on liquid-crystal display panels thereof. The cover has a through hole for a connection cable to pass through, which can provide a certain degree of positioning effect on the connection cable.

A liquid-crystal display projector according to the invention includes a projection lens, an optical light-converging component, a plurality of liquid-crystal display panels, a plurality of connection cables, and a cover. The optical light-converging component is disposed adjacent to the projection lens. The plurality of liquid-crystal display panels are disposed adjacent to the optical light-converging component. The plurality of connection cables are connected to the plurality of liquid-crystal display panels respectively. The cover is disposed above the optical light-converging component and the plurality of liquid-crystal display panels to cover the optical light-converging component and the plurality of liquid-crystal display panels. The cover has at least one through hole. The plurality of connection cables pass through the least one first through hole. Thereby, the cover can improve the dustproof effect on the plurality of liquid-crystal display panels. The through hole on the cover can provide a certain degree of positioning effect on the connection cable that passes through the through hole, which facilitates the connection operation of the connection cable (e.g. connected to a control circuit board in the liquid-crystal display projector).

Compared with the prior art, the liquid-crystal display projector according to the invention uses a cover having a through hole to provide both dustproof and positioning effects on the connection cables, which can effectively solve the difficulty of taking into account both dustproof and cable connection operation in the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a liquid-crystal display projector according to an embodiment.

FIG. 2 is a partially exploded view of the liquid-crystal display projector in FIG. 1.

FIG. 3 is another partially exploded view of the liquid-crystal display projector in FIG. 1.

FIG. 4 is an enlarged view of a portion of an optical engine in FIG. 3.

FIG. 5 is a schematic diagram illustrating a cover in FIG. 3 in another view point.

FIG. 6 is a schematic diagram illustrating a flow-guiding cover in FIG. 3 in another view point.

FIG. 7 is a schematic diagram illustrating the flow-guiding cover in FIG. 6 in another view point.

FIG. 8 is a sectional view of the liquid-crystal display projector along the line X-X in FIG. 2.

### DETAILED DESCRIPTION

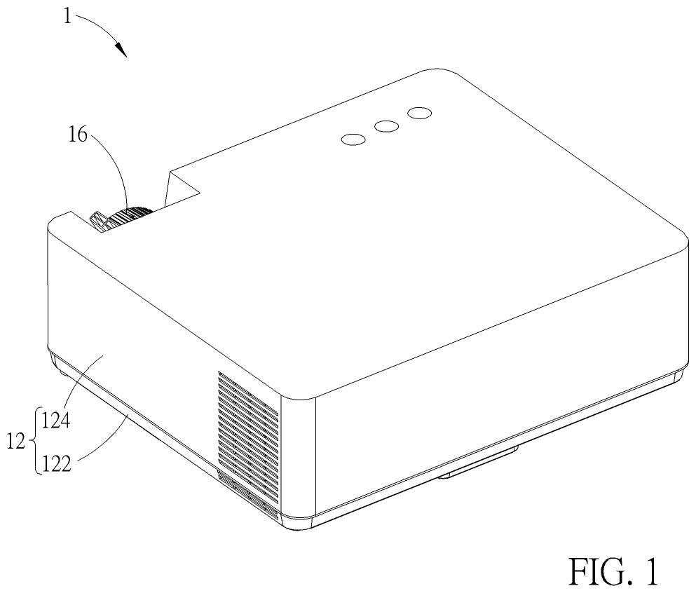

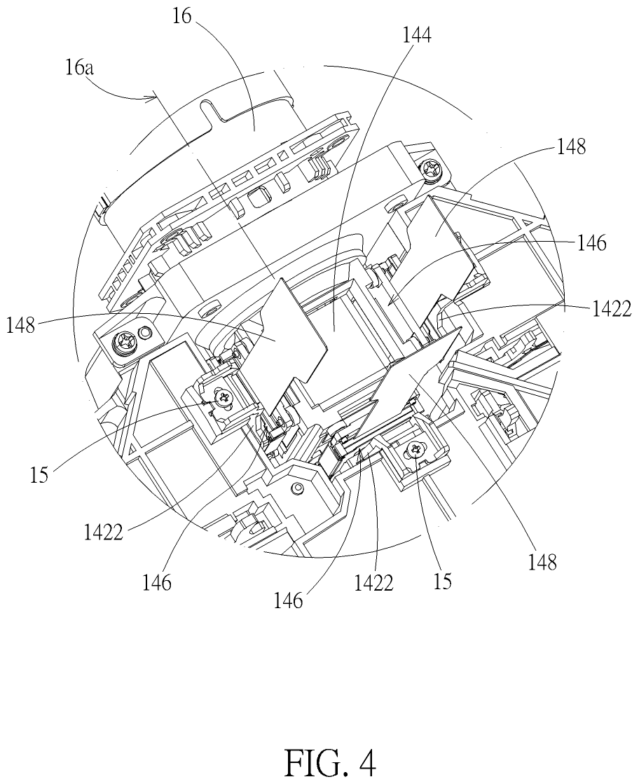

Please refer to FIG. 1 to FIG. 5. A liquid-crystal display projector 1 according to an embodiment includes an apparatus housing 12, an optical engine 14, a projection lens 16, a controller 18, a light source 20 (shown by a block in the figures), and other required devices (e.g. power supply) or structures (e.g. flow-guiding structure). The apparatus housing 12 includes a lower casing 122 and an upper casing 124. The lower casing 122 and the upper casing 124 are joined to form an accommodating space for accommodating the optical engine 14, the projection lens 16, the controller 18, the light source 20, and other devices or structures. The light source 20 and the projection lens 16 are disposed adjacent to the optical engine 14. The projection lens 16 is exposed from the apparatus housing 12. The controller 18 is electrically connected to the optical engine 14 and the light source 20 for controlling the light source 20 to provide light to the optical engine 14 and for controlling the optical engine 14 to modulate the light to be projected through the projection lens 16. In the embodiment, the controller 18 is realized by a circuit board module (that is shown by a plate structure in the figures and includes, for example but not limited to, a circuit board 182 and electronic components disposed on the circuit board 182, e.g. a processor, memory, connection interfaces and so on). The liquid-crystal display projector 1 also includes a system fan 22 (e.g. but not limited to an axial fan), disposed inside the apparatus housing 12 (in practice, or outside apparatus housing 12 in practice) for exhausting air inside the apparatus housing 12 (in practice, or drawing external air into the apparatus housing 12), which is conducive to heat dissipation of the liquid-crystal display projector 1.

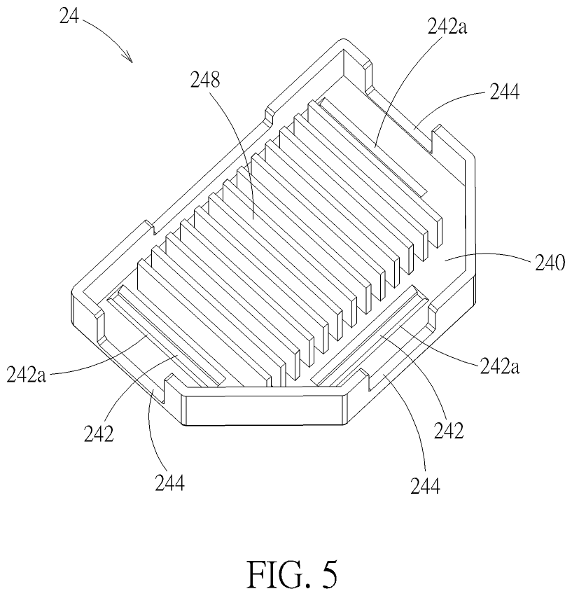

In the embodiment, the optical engine 14 includes an optical engine casing 142, an optical light-converging component 144, and a plurality of liquid-crystal display panels 146. The optical engine casing 142 contains a plurality of optical lenses (e.g. but not limited to including integrator lenses, beam splitters, reflectors, lenses and so on). The optical light-converging component 144 (e.g. but not limited to dichroic prism assembly, X cube) is disposed adjacent to the projection lens 16. The liquid-crystal display panels 146 are disposed adjacent to the optical light-converging component 144 and located between the optical light-converging component 144 and the optical engine casing 142. The liquid-crystal display panels 146 are connected to the controller 18 through a plurality of connection cables 148 correspondingly (i.e. the connection cable 148 being connected to the circuit board 182 and the corresponding liquid-crystal display panel 146). A cover 24 is disposed above the optical light-converging component 144 and the liquid-crystal display panels 146 to cover the optical light-converging component 144 and the liquid-crystal display panels 146. The cover 24 includes a cover body 240 and at least one first through hole 242 formed on the cover body 240. The connection cables 148 pass through the at least one first through hole 242. In the embodiment, the at least one first through hole 242, the plurality of liquid-crystal display panels 146, the plurality of connection cables 148 are the same in number; all are three. The first through hole 242 matches the cross-sectional profile of the connection cable 148 and is elongated. The connection cable 148 is a flexible board (e.g. but not limited to a flexible printed circuit board), which is convenient for passing through the corresponding first through hole 242 to be connected to the circuit board 182 during assembly. Furthermore, as shown by FIG. 5, the first through hole 242 has chamfered structures 242a at the inner side (i.e. the side toward the optical light-converging component 144), which is convenient for guiding the connection cable 148 to pass through the corresponding first through hole 242.

In the embodiment, the circuit board 182 covers the cover 24 (i.e. located above the cover 24) . The circuit board 182 has at least one second through hole 1822 (of which the number is three corresponding to the connection cables 148). The connection cable 148 passes through the corresponding second through hole 1822 to be connected to a corresponding connector 184 (shown by a strip structure in the figures) disposed on a surface of the circuit board 182 opposite to the cover 24, so as to obtain the electrical connection between the liquid-crystal display panel 146 and the circuit board 182. Furthermore, in the embodiment, the first through hole 242 is aligned with the second through hole 1822 and located above the corresponding liquid-crystal display panel 146. The structural configuration is convenient for passing the connection cable 148 through the corresponding first through hole 242 and the corresponding second through hole 1822 during assembly. Furthermore, in the embodiment, the cover 24 (or the cover body 240 thereof) covers both the optical light-converging component 144 and the liquid-crystal display panels 146, and there is no opening formed on the portion of the cover body 240 above the optical light-converging component 144 and the liquid-crystal display panels 146. Therefore, the structural configuration can prevent the dust from directly falling in, thereby providing a certain degree of dustproof effect on the optical light-converging component 144 and the liquid-crystal display panels 146. Furthermore, the cover 24 substantially fits to the optical engine casing 142; therein, the cover 24 has an indentation 244 on each of its three sides (i.e. formed on the edge of the side wall of the cover body 240). The indentations 244 fit to holding parts 1422 of the optical engine casing 142 used for holding the optical components. In practice, the cover 24 also can be joined to the optical engine casing 142 in other structurally joining ways, e.g. but not limited to securing (e.g. fixing the cover 24 together with the holding parts 1422 to the optical engine casing 142 with screws 15), structural engagement, and the like. Furthermore, in practice, the dustproof effect can be improved by increasing the structural closeness between the cover 24 and the optical engine casing 142.

Furthermore, in the embodiment, the cover 24 can be made of thermally conductive materials (e.g. but not limited to thermally conductive plastics, copper, aluminum, or other metals or alloys), so the cover 24 can conduct heat and thus can provide a heat dissipation effect on the optical light-converging component 144 and the liquid-crystal display panels 146. The cover 24 also includes a plurality of outward fins 246 extending outward from the cover body 240, and a plurality of inward fins 248 extending inward from the cover body 240 opposite to the outward fins 246. The outward fins 246 and the inward fins 248 are located above the optical light-converging component 144. The outward fins 246 help heat from the cover body 240 to be dissipated out. The inward fin 248 helps heat accumulated in the optical light-converging component 144 to be transferred to the cover body 240. Thereby, both the outward fins 246 and the inward fins 248 help to improve the heat dissipation efficiency, and can be implemented alternatively. Furthermore, in practice, the outward fins 246 and the inward fins 248 are not limited to be formed in the plate shape shown in the figures (e.g. formed in a column shape), and are not limited to have the same shape. In addition, when the cover 24 is made of metal, the cover 24 can produce a filtering effect and reduce EMI to the connection cable 148 by passing the connection cable 148 through the cover 24.

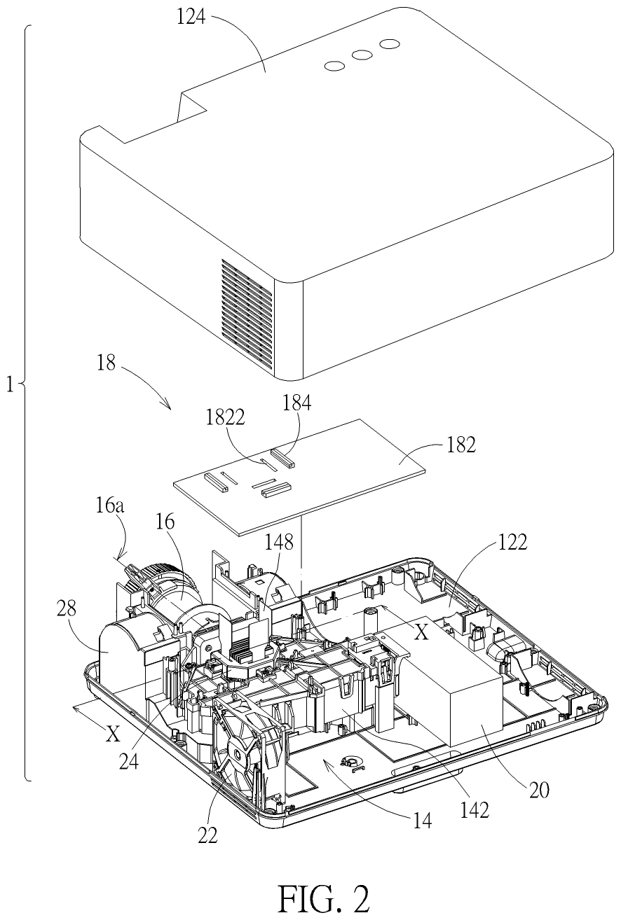

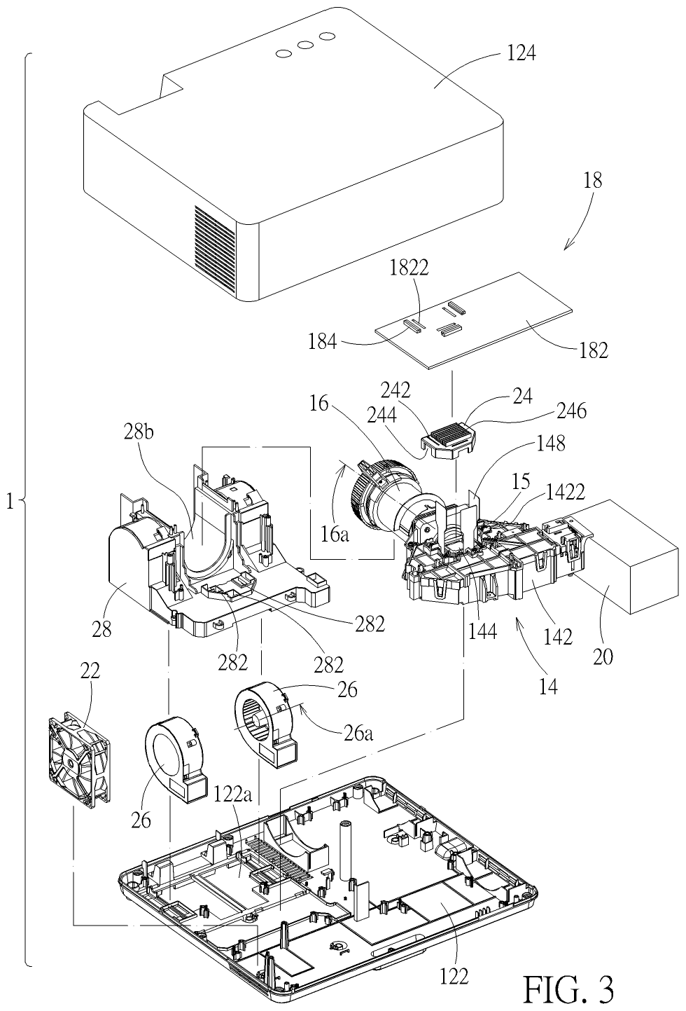

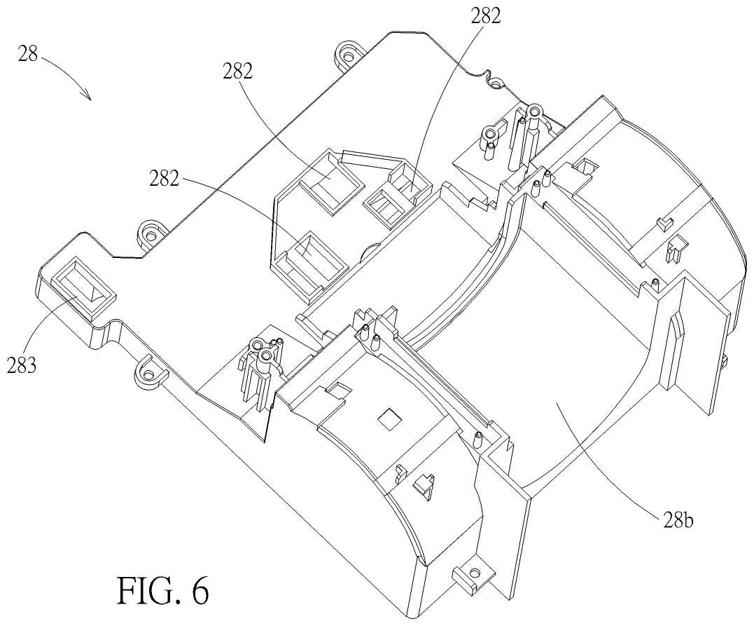

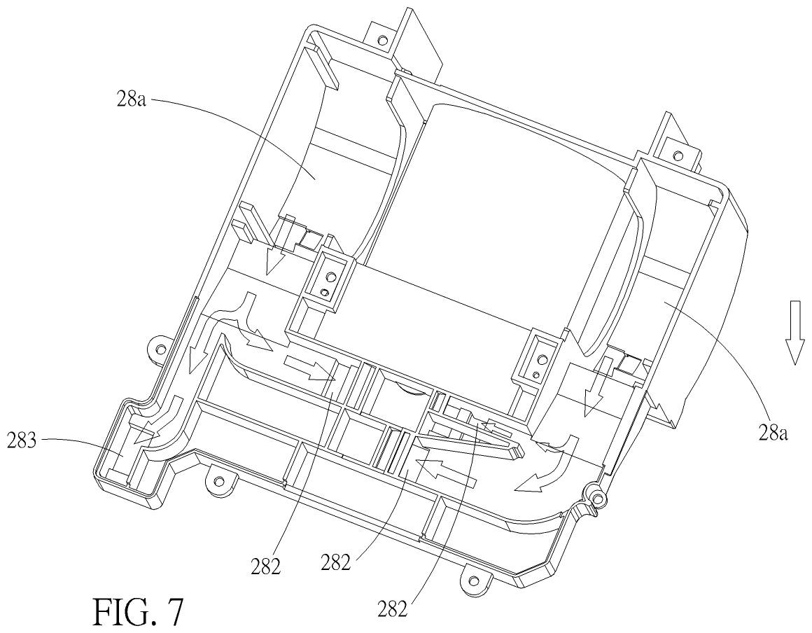

Please refer to FIG. 2, FIG. 3, FIG. 6 and FIG. 7. In the embodiment, the liquid-crystal display projector 1 further includes an airflow generating device and a flow-guiding cover 28. The flow-guiding cover 28 and the lower casing 122 are joined together to forma flow-guiding structure. An airflow generated by the airflow generating device is guided by the flow-guiding structure to blow to the liquid-crystal display panels 146 for dissipating heat therefrom. The flow-guiding structure has three airflow outlets 282 (formed on the flow-guiding cover 28) disposed toward and under the liquid-crystal display panels 146 respectively. The airflow generating device includes two heat dissipation fans 26 (e.g. but not limited to centrifugal fans or axial fans). The heat dissipation fans 26 are accommodated in the accommodating space 28a formed at the inside of the flow-guiding cover 28, and the projection lens 16 is accommodated in a recess 28b formed at the outside of the flow-guiding cover 28, so that the heat dissipation fan 26 is disposed adjacent to the projection lens 16 and located at the two sides of the projection lens 16. This structural configuration is conducive to reduction of the volume of liquid-crystal display projector 1. In the embodiment, the heat dissipation fan 26 has a blade rotation axis 26a (indicated by a chain line in FIG. 2 and FIG. 3). The projection lens 16 has an optical axis 16a (indicated by a chain line in FIG. 2 and FIG. 3). The blade rotation axis 26a is perpendicular to the optical axis 16a. This structural configuration makes the heat dissipation fans 26 closer to the projection lens 16, which helps to reduce the volume of the liquid-crystal display projector 1.

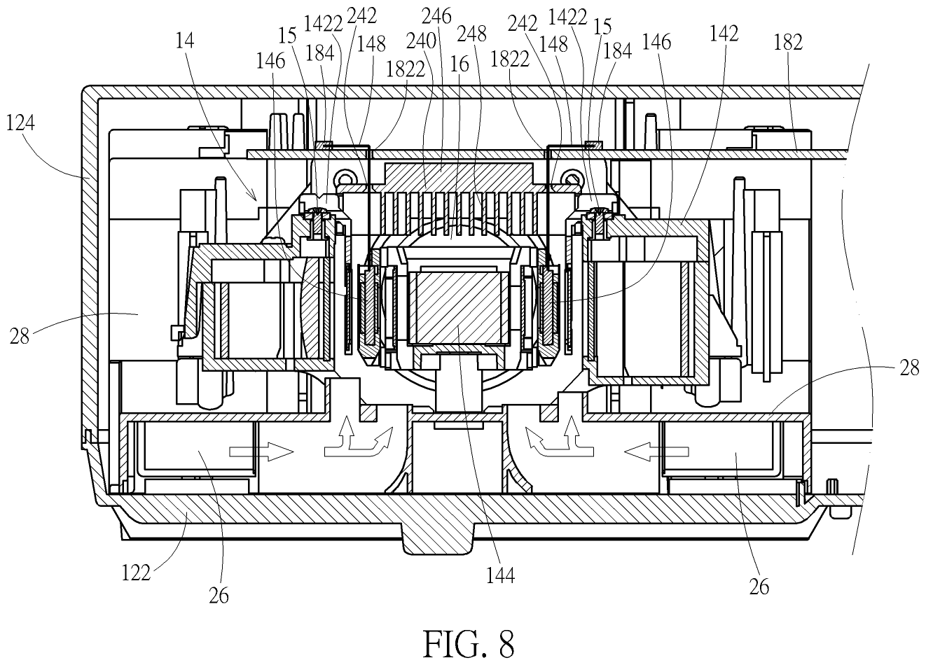

Please also refer to FIG. 8. The airflow generated by the heat dissipation fan 26 (of which the flowing path in the flow-guiding cover 28 is indicated by hollow arrows in FIG. 7 and FIG. 8) blows to the corresponding liquid-crystal display panels 146 through the airflow outlets 282, so as to dissipate heat. The optical light-converging component 144 and the liquid-crystal display panels 146 are adjacently disposed, so the airflow also helps to dissipate heat from the optical light-converging component 144. Furthermore, in the embodiment, the airflow outlets 282 are orientated upward and toward the cover 24. The liquid-crystal display panel 146 is located between the airflow outlets 282 and the cover 24. This structural configuration can take advantage of the characteristics of hot air automatically flowing upward, which is conducive to the flow and heat transfer (including heat from the optical light-converging component 144 and liquid-crystal display panels 146 transferred to the cover 24 through the airflow) of the airflow, enhancing the heat dissipation efficiency.

In addition, in the embodiment, one of the heat dissipation fans 26 corresponds to one of the airflow outlets 282, and the other one heat dissipation fan 26 corresponds to the other two airflow outlets 282. However, it is not limited thereto in practice. For example, in the flow-guiding cover 28, the three airflow outlets 282 can communicate with each other, which helps to balance the amount of the airflow received by each liquid-crystal display panel 146. For another example, the flow-guiding cover 28 can use more or less airflow outlets to provide the airflow to the liquid-crystal display panels 146 for heat dissipation. Furthermore, in the embodiment, the flow-guiding cover 28 further includes an airflow outlet 283 aligned with an inlet (not shown in the figures) of the optical engine 14 (or the optical engine casing 142 thereof), so that the heat dissipation fan 26 also provide an airflow for heat dissipation to the optical engine 14 through the airflow outlet 283.

In addition, a portion of the lower casing 122 that is joined with the flow-guiding cover 28 to form the flow-guiding structure forms an intake opening 122a. The external air outside the liquid-crystal display projector 1 enters the flow-guiding cover 28 through the intake opening 122a and then is pressurized by heat dissipation fans 26 to form the airflow. In practice, it is practicable to dispose a filtering structure (e.g. including but not limited to filter screens or cloths made of fibers or porous materials) at the intake opening 122a, for filtering out or reducing the particles contained in the incoming air.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid-crystal display projector, comprising:
a projection lens;
an optical light-converging component, disposed adjacent to the projection lens;
a plurality of liquid-crystal display panels, disposed adjacent to the optical light-converging component;
a plurality of connection cables, connected to the plurality of liquid-crystal display panels respectively; and
a cover, disposed above the optical light-converging component and the plurality of liquid-crystal display panels to cover the optical light-converging component and the plurality of liquid-crystal display panels, the cover having at least one first through hole, the plurality of connection cables passing through the least one first through hole.

2. The liquid-crystal display projector according to claim 1, further comprising a circuit board, disposed above the cover and having at least one second through hole, wherein the plurality of connection cables pass through the at least one second through hole to be connected to the circuit board.

3. The liquid-crystal display projector according to claim 2, wherein the at least one first through hole and the plurality of connection cables are the same in number, and the plurality of connection cables pass through the at least one first through hole respectively.

4. The liquid-crystal display projector according to claim 3, wherein the first through hole is located above the corresponding liquid-crystal display panel.

5. The liquid-crystal display projector according to claim 3, wherein the at least one second through hole and the at least one first through hole are the same in number, and the second through hole is located above the corresponding first through hole.

6. The liquid-crystal display projector according to claim 1, wherein the cover is thermally conductive, and the cover comprises a cover body and a plurality of outward fins extending outward from the cover body.

7. The liquid-crystal display projector according to claim 6, wherein the outward fins are located above the optical light-converging component.

8. The liquid-crystal display projector according to claim 6, wherein the cover comprises a plurality of inward fins, extending inward from the cover body opposite to the outward fins.

9. The liquid-crystal display projector according to claim 1, further comprising an airflow generating device and a flow-guiding structure, wherein the flow-guiding structure has at least one airflow outlet toward and under the plurality of liquid-crystal display panels, and an airflow generated by the airflow generating device is guided by the flow-guiding structure to blow to the plurality of liquid-crystal display panels through the at least one airflow outlet.

10. The liquid-crystal display projector according to claim 9, wherein the airflow generating device comprises a heat dissipation fan, disposed adjacent to the projection lens.

11. The liquid-crystal display projector according to claim 10, wherein the heat dissipation fan has a blade rotation axis, the projection lens has an optical axis, and the blade rotation axis is perpendicular to the optical axis.

12. The liquid-crystal display projector according to claim 9, wherein the at least one airflow outlet and the plurality of liquid-crystal display panels are the same in number, and the airflow outlet is toward the corresponding liquid-crystal display panel.

13. The liquid-crystal display projector according to claim 1, further comprising an optical engine casing, wherein the cover is joined with the optical engine casing.

14. The liquid-crystal display projector according to claim 1, further comprising an apparatus housing and a system fan, wherein the projection lens, the optical light-converging component, the plurality of liquid-crystal display panels, the plurality of connection cables, and the cover are disposed in the apparatus housing, the projection lens is exposed from the apparatus housing, and the system fan is disposed on the apparatus housing to exhaust air inside the apparatus housing.
